(19) United States
(12) Patent Application Publication
(10) Pub. No.: US 2007/0194301 A1
(43) Pub. Date: Aug. 23, 2007

(54) Semiconductor arrangement with non-volatile memories

(76) Inventors: Recai Sezi, Roettenbach (DE); Andreas Walter, Dresden (DE); Reimund Engl, Regensburg (DE); Anna Maltenberger, Leutenbach (DE); Christine Dehm, Nuernberg (DE); Sitaram Arkalgud, Cedar Park, TX (US); Igor Kasko, Mennecy (FR); Joachim Nuetzel, Dresden (DE); Jakob Kriz, Weinboehla (DE); Thomas Mikolajick, Dresden (DE); Cay-Uwe Pinnow, Corbeil-Essonnes (FR)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 10/580,881

(22) PCT Filed: Nov. 24, 2004
(86) PCT No.: PCT/DE04/02601

§ 371 Date: May 1, 2007

(30) Foreign Application Priority Data
Nov. 28, 2003 (DE) 103 55 561.7

(51) Int. Cl. H01L 51/00; H01L 21/8232

(52) U.S. Cl. 257/40; 438/142; 257/E51.02

(57) ABSTRACT

One aspect of the invention relates to a semiconductor arrangement having at least one nonvolatile memory cell which has a first electrode comprising at least two layers; and having an organic material, the organic material forming a compound with that layer of the first electrode which is in direct contact. One aspect of the invention furthermore relates to a method for producing the nonvolatile memory cell, a semiconductor arrangement having a plurality of memory cells according to the invention, and a method for producing the same.

### BACKGROUND

One aspect of the invention relates to a semiconductor arrangement having nonvolatile memories. Various cells which can be used in the production of semiconductors are known from the prior art. U.S. Pat. No. 4,371,883 describes a cell which has a film made of an organic material between two metal electrodes, the electron acceptor forming a charge transfer complex (CT complex) with one of the electrodes, which includes copper (Cu) or silver (Ag). The organic material described in U.S. Pat. No. 4,371,883 is for example tetracyanoquinodimethane (TCNQ), tetracyanonaphthoquinodimethane (TNAP), tetracyanoethylene (TCNE), dichlorodicyanobenzoquinone (DDQ), or the derivatives thereof. Using an electric field, the cell can be switched between two states having different resistances (ON state and OFF state), so that these two states can be assessed for example as “0” or “1”.

The cell in accordance with U.S. Pat. No. 4,371,883 has significant disadvantages, however, so that such a cell is not appropriate for use in microelectronics. One disadvantage of the cell in accordance with U.S. Pat. No. 4,371,883 consists, inter alia, in the fact that the film thickness deemed necessary lies between 1 and 10 μm. The further disadvantage is that the ratio between the resistances of the ON and OFF states is very low and amounts to only 66, and also that the construction of the cell in accordance with U.S. Pat. No. 4,371,883 is not compatible with the customary constructions in microelectronics. Thus, by way of example, electrodes such as gold, magnesium or chromium are avoided in chipmaking. The crucial disadvantage, however, is that the cell cannot be used as a nonvolatile memory cell since such a cell undergoes transition from the ON state to the OFF state after the electric field has been switched off (U.S. Pat. No. 4,371,883, column 5, lines 15-17). The transition time is dependent on the film thickness. Further embodiments of such cells are described, for example, in U.S. Pat. No. 4,652,894 or 5,161,149.

### SUMMARY

One aspect of the present invention is to provide a semiconductor arrangement having a nonvolatile memory cell which enables a high integration density, is compatible with the customary production methods in microelectronics and has improved properties compared with the memory cells in accordance with the prior art.

Aspects of the cell construction according to embodiments the invention are reversible switchability, a ratio between ON and OFF resistances of up to 1000 or higher nondestructive reading since there is no need for rewriting after reading, since the cell operates according to a resistive principle, scalability up to an area of 40 nm², nonvolatile information storage, functionality down to film thicknesses of approximately 30 nm, a thermal stability up to 350° C., the functional capability of the cell even at a temperature of up to 200° C., good adhesion of the layers to one another, switchability in the presence of air and moisture, selective formation of the electrical switchable chemical substance directly above the electrode, so that in the presence of an insulator, such as for example, silicon dioxide, the complex is formed only above the electrode, simple and cost-effective production of the complex, and the suitability of the memory cell for production in a plurality of layers, such as for example, in the Cu damascene technique.

The semiconductor arrangement having a nonvolatile memory cell according to one embodiment of the invention includes a substrate, which has two electrodes and an organic material situated in between (identified as material X in the drawings), one electrode forming the compound with the organic material. This “compound” may arise with the formation of covalent or ionic bonds, but also with the formation of charge transfer complexes or of weak bonds such as dipole-dipole interactions, etc.

Apart from organic materials, it is also possible to use inorganic or inorganic-organic materials (likewise as material X) in order to form the abovementioned compound. These materials are sulphur, selenium or tellurium either in pure or in bonded form (that is to say organocompounds of sulphur, selenium or tellurium, and, if appropriate, oligomers or polymers). Since organic materials are predominantly used, however, the material is defined as an organic material below. The organic material in some embodiment is selected from the following group:

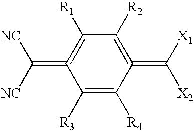

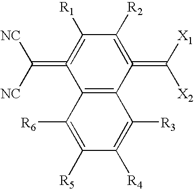

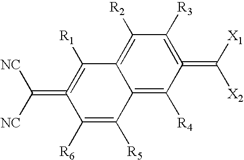

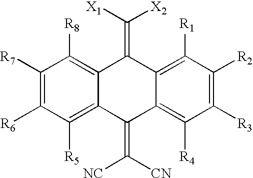

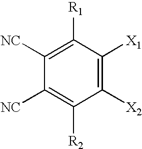

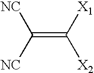

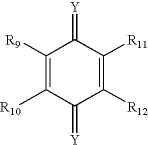

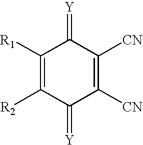

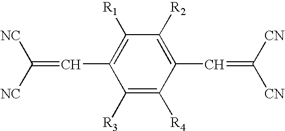

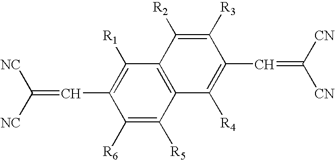

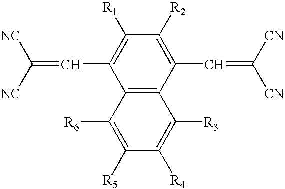

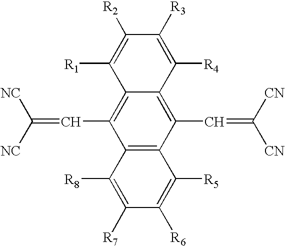

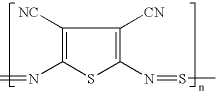

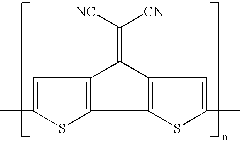

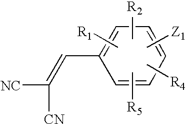

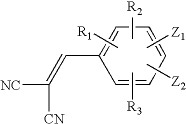

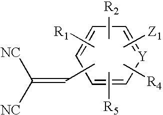

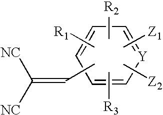

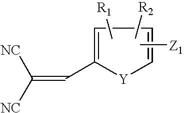

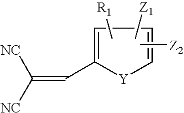

where R₁, R₂, R₃, R₄, R₅, R₆, R₇ and R₈, independently of one another, have the following meaning:

H, F, Cl, Br, I (iodine), alkyl, alkenyl, alkynyl, O-alkyl, O-alkenyl, O-alkynyl, S-alkyl, S-alkenyl, S-alkynyl, OH, SH, aryl, heteroaryl, O-aryl, S-aryl, NH-aryl, O-heteroaryl, S-heteroaryl, CN, NO₂, —(CF₂)ₙ—CF₃, —CF((CF₂)ₙCF₃)₂, -Q-(CF₂)ₙ—CF₃, —CF(CF₃)₂, —C(CF₃)₃ and

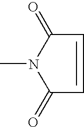

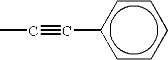

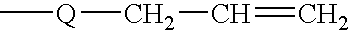

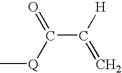

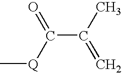

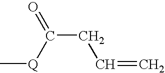

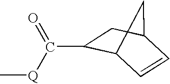

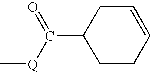

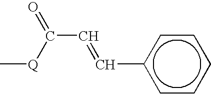

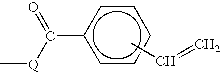

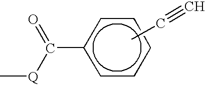

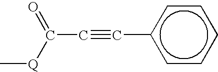

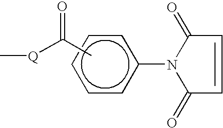

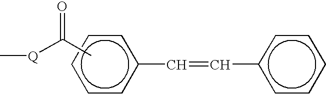

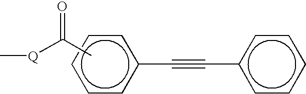

the following holds true for n: n=0 to 10
the following holds true for Q: —O—, —S—
R₉, R₁₀, R₁₁, R₁₂ may, independently of one another, be:
F, Cl, Br, I, CN, NO₂
R₁₃, R₁₄, R₁₅, R₁₆, R₁₇ may, independently of one another, be:
H, F, Cl, Br, I, CN, NO₂

X₁ and X₂ may, independently of one another, be:

CN

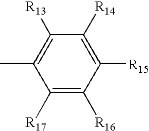

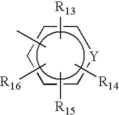

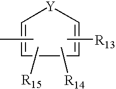

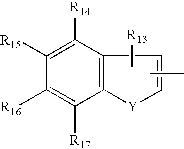

the following holds true for Y: O, S, Se. The following holds true for Z₁ and Z₂, independently of one another: CN, NO₂.

The substrate may be silicon, germanium, gallium arsenide, gallium nitride; an arbitrary material containing an arbitrary compound of silicon, germanium or gallium; a polymer (that is to say plastic; filled or unfilled; for example, as molding or film), ceramic, glass or metal. Said substrate may also be an already processed material and contain one to a plurality of layers comprising contacts, interconnects, insulating layers and further microelectronic components.

The substrate is in one case silicon which has already been correspondingly subjected to front end of line (FEOL) processing, that is to say already contains electrical components such as transistors, capacitors, etc.—fabricated using a silicon technology. There is in one case an insulating layer situated between the substrate and the nearest electrode; particularly when the substrate is electrically conductive. However, there may also be a plurality of layers between the substrate and the nearest electrode.

The substrate may serve only as carrier material or else fulfill an electrical function (evaluation, control). For the last-mentioned case, there are electrical contacts between the substrate and the electrodes applied to the substrate. Said electrical contacts are for example contact holes (vias) filled with an electrical conductor. However, it is also possible for the contacts to be effected from lower layers into the upper layers, through metallizations in the edge regions of the substrate or of the chips.

One exemplary device of the invention is the so-called hybrid memory, the substrate being processed using customary front end of the line (FEOL) CMOS silicon technology and the memory layer(s) subsequently being applied thereto. However, the substrate, as mentioned above, is not just restricted to this.

The above-described sandwich structure of the memory cell(s), including two electrodes and the intervening organic material or the compound formed, can be applied to the substrate not just once but a number of times in a form stacked one above another. This gives rise to a plurality of “planes” for the memory cells, each plane including two electrodes and the intervening compound (the electrodes adjoin the two areas of the compound). Of course, there may also be a plurality of cells in one plane (cell array). The different planes can be isolated from one another by means of an insulator. It is also possible for only three electrodes, rather than four electrodes, to be used for two planes lying one above the other; in other words, the “middle” electrode is utilized jointly.

It has been ascertained that the cell according to embodiments of the invention in the semiconductor arrangement can retain the applied state without an applied voltage for a very long time, so that the cell can therefore serve as a nonvolatile memory. It was able to be shown that the semiconductor arrangement according to embodiments of the invention having the cell according to the invention is still clearly readable or else functionally capable even after thousands of cycles of the ON/OFF alternation and can even retain the applied state for several months. The electrode facing the substrate (identified hereinafter as bottom electrode) in one case includes at least two layers, in which case the layer which is directly in contact with the substrate (identified hereinafter as layer 1 of the bottom electrode) may be titanium (Ti), titanium nitride (TiN), tantalum (Ta), tantalum nitride (TaN), tungsten (W), furthermore TiW, TaW, WN or WCN, and IrO, RuO, SrRuO or any desired combination of these materials—including in two or more layers. Furthermore, in combination with the abovementioned layers or materials, thin layers made of Si, TiNSi, SiON, SiO, SiC, SiN or SiCN may also be present. Consequently, layer 1 of the bottom electrode itself may include more than one layer.

The abbreviations TiN, TaN, etc. are only symbolic, that is to say that they do not reproduce exact stoichiometric ratios (by way of example, silicon dioxide here is also not identified as SiO2, but as SiO). The ratio of the components can be changed as desired within possible limits. The other layer (identified hereinafter as layer 2 of the bottom electrode) has a metal, in one case copper, which forms the abovementioned compound with the organic material (material X). This layer (layer 2) which forms the compound may be either pure metal or an alloy of a plurality of metals. What is crucial, however, is that this layer contains a metal which can form the compound with the organic material. In one case, the material is copper and its alloys with other metals. Silver or its alloys with other metals is additionally suitable.

Various methods are suitable for depositing the abovementioned layers. Said methods may be for example, PVD, CVD, PECVD, vapor deposition, electroplating, electroless plating or atomic layer CVD (ALCVD); however, the methods are not just restricted to these methods.

The second electrode (top electrode) may include one or a plurality of layers. The second electrode may be aluminum, copper, silver, AlCu, AlSiCu, titanium (Ti), titanium nitride (TiN), tantalum (Ta), tantalum nitride (TaN), tungsten (W), furthermore TiW, TaW, WN or WCN, and IrO, RuO, SrRuO or any desired combination of these materials—including in two or more layers. Furthermore, in combination with the abovementioned layers or materials, thin layers made of Si, TiNSi, SiON, SiO, SiC, SiN or SiCN may also be present. Consequently, layer 1 of the bottom electrode itself may include more than one layer.

However, the type of suitable electrodes is not restricted to the abovementoined materials.

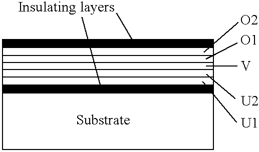

O2 = layer 2 of the top electrode
O1 = layer 1 of the top electrode
V = compound formed
U2 = layer 2 of the bottom electrode
U1 = layer 1 of the bottom electrode

Insulating layers ₀₂ Substrate U

O2=layer 2 of the top electrode

O1=layer 1 of the top electrode

V=compound formed

U2=layer 2 of the bottom electrode

U1=layer 1 of the bottom electrode

The organic material arranged between the electrodes is in one case an electron acceptor, that is to say a molecule having electron-attracting atoms (for example, —Cl, —F, —Br, —I) or groups (for example, —CN, —CO—, —NO₂) and forms the corresponding compound with the bottom electrode. In particular, those molecules which contain at least one of the abovementioned atoms and/or groups in their skeleton are in one case preferred as electron acceptor. Of course, a plurality of the abovementioned atoms or groups may likewise be present. In one case, the organic materials are TCNQ and DDQ. The compound is formed by a selective reaction of the organic material with layer 2 of the bottom electrode, which for example, contains copper or contains silver. The composition of the bottom electrode and of the organic material is not restricted to TCNQ and copper, but rather may on the one hand include arbitrary organic materials (which contain at least one of the abovementioned atoms or groups) and on the other hand include arbitrary metals. It is only necessary for the electrode to contain a metal which forms the compound with the organic material or with a component of the organic material. The suitable organic material may correspond for example to one of the structures listed in table 1. It is also possible for more than one of the molecules mentioned in table 1 to form the compound with the metal. However, the number of electron acceptors is not limited to the molecules listed in table 1.

Besides the abovementioned electron acceptors, other materials such as for example sulphur in elemental form or sulphur-containing organic compounds may also form the compound with the (bottom) electrode (for example copper sulphide). Furthermore, by way of example, selenium or selenium-containing compounds or tellurium or tellurium-containing compounds may also form a compound with the bottom electrode.

The properties of the cell according to embodiments of the invention are illustrated in table 2.

| | |
|---|---|
| Retention time | >350 days |
| Endurance | up to 100.000 cycles |
| Threshold voltage (switching) | ≧2 V |
| Ratio of the ON and OFF resistances | up to 10.000 |
| Imprint (writing or erasure) | ≧1 million pulses |
| Read pulses | ≧10 million pulses |
| Scalability | 40 nm² |
| Lithographic process directly above the cell | Possible |

Explanations:

Threshold voltage: voltage at which the cell switches from the OFF (ON) to the ON(OFF) state.

Retention time: period of time in which the memory state (ON or OFF) is retained without an applied voltage.

Endurance: number of maximum possible write and erase cycles/pulses. Imprint: number of maximum possible (single-sided) write or erase pulses without the properties (threshold voltage, values for ON and OFF resistances, profile of the U-I diagram, etc.) exhibiting a significant, lasting change.

Read: number of maximum possible read pulses.

A boundary condition for all is that the cells do not break down in the context of the experiments or the electrical values do not exceed specific permitted tolerances.

The semiconductor arrangement according to embodiments of the invention may also have a plurality of nonvolatile memory cells and the plurality of cells may be incorporated into the semiconductor arrangement with a high integration density.

The method for producing the semiconductor arrangement is described below.

In order to produce the semiconductor arrangement having the memory cell according to embodiments of the invention, firstly a substrate is provided.

The substrate may be, as described above, silicon, germanium, gallium arsenide, gallium nitride; an arbitrary material containing an arbitrary compound of silicon, germanium or gallium; a polymer (that is to say plastic; filled or unfilled; for example, as molding or film), ceramic, glass or metal. Said substrate may also be an already processed material and contain one to a plurality of layers comprising contacts, interconnects, insulating layers and further microelectronic components.

The substrate is in one case silicon, which has already been correspondingly subjected to front end of line (FEOL) processing, that is to say already contains electrical components such as transistors, capacitors, etc.—fabricated using a silicon technology. There is in one case an insulating layer situated between the substrate and the nearest electrode; particularly when the substrate is electrically conductive. However, there may also be a plurality of layers between the substrate and the nearest electrode.

The substrate may serve only as carrier material or else fulfill an electrical function (evaluation, control). For the last-mentioned case, there are electrical contacts between the substrate and the electrodes applied to the substrate. Said electrical contacts are for example contact holes (vias) filled with an electrical conductor. However, it is also possible for the contacts to be effected from lower layers into the upper layers, through metallizations in the edge regions of the substrate or of the chips.

Firstly, the bottom electrode is applied to the substrate. There is optionally an insulating layer situated between the substrate and the bottom electrode; in one case, this is a necessity, however, when the substrate or the topmost layer of the substrate is electrically conductive. In the case of silicon as substrate, said insulating layer may be for example silicon oxide. The bottom electrode introduced into the substrate includes at least two layers and can be produced by the methods described below.

The electrode may be deposited from the gas phase or from solution. Methods such as for example PVD, CVD, PECVD, vapor deposition, electroplating, electroless plating or atomic layer CVD (ALCVD) are suitable for this purpose. The layers U1 and U2 are for example deposited one after the other and subsequently patterned. For this purpose, a photoresist is applied to the layer U2 and this is patterned according to customary methods (exposure, development, etc.). This structure is then transferred into the two layers by means of etching using a gas or a gas mixture or else using a liquid or liquid mixture. The etching of the two layers may be effected using the same reagent (gas or liquid) or else may require different reagents.

Apart from patterning by etching, the layers may also be patterned by means of the so-called damascene technique. For this purpose, by way of example, an insulating layer (in one case silicon oxide) lying above the substrate is patterned by lithography and etching. After stripping of the photoresist, the two layers are deposited, so that the trenches or holes in the insulating layer that have arisen during the patterning are completely filled with the electrode materials. That part of these materials which protrudes above the surface of the insulating layer is subsequently ground back. The grinding process may be effected by means of the so-called CMP technique (CMP=chemical mechanical planarization or chemical mechanical polishing). This gives rise to, for example, interconnects and/or contact holes which are filled with the electrode materials and are embedded in the insulating layer or have exactly the same height as the insulating layer.

Layer 2 of the bottom electrode (U2) is in one case copper or copper-containing and forms the corresponding compound with the organic material, which is subsequently applied. It may also be silver-containing. The organic material may be applied to the electrode (for example, in a solvent mixture). If the organic material is TCNQ, a solvent mixture including at least two solvents is used in one case, one of said solvents in one case being acetonitrile or proprionitrile or some other solvent which contains —CN groups. The second solvent is in one case a ketone, an alcohol, an ester, an aromatic, an aliphatic or cycloaliphatic or an ether and mixtures thereof. The following are suitable by way of example: acetone, diethylketone, cyclohexanone, cyclopentanone, butanone, cyclohexane, gamma-butyrolactone, ethyl acetate, ethoxyethyl acetate, methoxypropyl acetate, ethyoxyethyl proprionate, ethyl alcohol, propyl alcohol, iso-propanol, dibutyl ether, tetrahydrofuran, chlorobenzene, benzyl alcohol. The duration of this treatment may be between 10 seconds and 10 minutes. The treatment temperature is between −20 and 100° C., depending on the properties of the solvents. Solvent mixtures are also suitable for many substances mentioned in table 1. The proportion of the solvent which contains the —CN group is 0.01 to 65% by volume. Its proportion depends on the composition of the entire solution. This solution may also contain more than two solvents and likewise also more than one organic material (that is to say material X).

Rinsing is then effected using one of the abovementioned solvents, such as acetone for example. This rinsing step serves in one case for removing the excess TCNQ from the substrate, so that only the compound formed remains in the region of the electrode, since the compound can be formed only in this region.

The organic material may also be vapor-deposited onto the bottom electrode. After the vapor deposition, it is necessary to subject the substrate to a thermal treatment in order to produce the compound. It is only after this thermal treatment that the substrate can be rinsed with a solvent in order to remove the excess TCNQ. If the organic material is vapor-deposited onto the electrode, it is advantageous in one case if the vapor deposition time is between 2 and 30 min. The pressure to be used lies in a range of between 0.000001 and 200 mbar and the vapor deposition is carried out at a substrate temperature of between −50 and 150° C. It is also possible for not just one but two or more organic materials X to be vapor-deposited onto the electrode simultaneously or one after another.

The properties of the semiconductor arrangement having the memory cell may additionally be improved if the compound formed in the case of a cell produced according to the method described above is subjected to an aftertreatment, to be precise in one case directly after the formation of the compound, sometimes even during the formation of the compound. The aftertreatment is effected by contacting the compound with a solution of an aftertreatment reagent. In some cases, amines, amides, ethers, ketones, carboxylic acids, thioethers, esters, aromatics, heteroaromatics, alcohols or various sulphur- or selenium-containing compounds such as for example, sulphur heterocyclic compounds, compounds with —SO— groups or thiols are appropriate as the aftertreatment reagent, but the number of suitable reagents is not just restricted to these. The reagents may additionally contain unsaturated groups as well as saturated groups. Examples of aftertreatment reagents are diethylamine, triethylamine, dimethylaniline, cyclohexylamine, diphenylamine, dimethylformamide, dimethylacetamide, dimethyl sulfoxide, acetone, diethylketone, diphenylketone, phenyl benzoate, benzofuran, N-methylpyrrolidone, gamma-butyrolactone, toluene, xylene, mesitylene, naphthaline, anthracene, imidazole, oxazole, benzimidazole, benzoxazole, quinoline, quinoxaline, fulvalene, furan, pyrrole, thiophene or diphenyl sulfide. The treatment time is in one case between 15 s and 15 min at a temperature of in one case −30 to 100° C., either in air or under an inert gas, such as for example, nitrogen or argon.

Experience shows that the aftertreatment reagent may be concomitantly incorporated into the memory cell or it may be attached to the cell. The existence of the aftertreatment reagent can be demonstrated for example after thermodesorption at higher temperatures by means of gas chromatography GC or mass spectroscopy MS. Surprisingly, even very small quantities (from a few ppm) of the incorporated or attached aftertreatment reagent can cause significant improvements in the properties of the memory cell. However, the incorporation of the aftertreatment reagent is not a necessity for improving the properties; under certain circumstances, an aftertreatment also suffices for this purpose without an incorporation being detected by means of GC or MS.

As an alternative, the compound may be contacted with gaseous (or vapor) aftertreatment reagent. In air or under an inert gas, such as for example, nitrogen or argon, the aftertreatment proceeds at a pressure of 0.00001 to 1000 mbar at a substrate temperature of between −30 and 150° C. A thermal step may subsequently follow, but is not always necessary.

A cell that has been subjected to aftertreatment in this way has an improved (that is to say lower) threshold voltage during switching of the cell by up to 40%, a ratio between the ON and OFF states which is 10 times as high as in the case of a cell that has not been subjected to aftertreatment, and up to 100-fold higher endurance and improved imprint characteristics and an improvement of the layer adhesion by up to 20%.

Some of the “aftertreatment reagents” may, however, also be vapor-deposited at the same time as the material X or else directly in succession (they likewise afford the abovementioned advantages), so that they are jointly subjected to the subsequent thermal step.

A further aspect of the invention relates to an integration concept for a semiconductor arrangement having a plurality of cells according to the invention. The cell according to some embodiments of the invention may be situated in the semiconductor arrangement between a word line and a bit line which cross one another perpendicularly. The cell is then switched into the ON or OFF state by corresponding voltages being applied to the word line and the bit line. The state of the cell can thus be altered. The ON and OFF states correspond for example to the states having lower and higher electrical resistance, respectively.

In general, the electrodes are produced in such a way that they serve as a word or bit line. However, the situation may also be that an (additional) layer of the top and/or bottom electrode is applied only in the region of the cell—in direct contact with the compound—, that is to say not along the entire interconnect (word or bit line). This relates in one case to the via concept described further below.

In the case of a “crosspoint” construction, the individual memory cells lie directly between interconnects that cross one another and form bit and word lines. In order to produce the individual cells, it is possible, by way of example, for the bottom electrodes to be completely covered with the compound and the top electrodes to be applied thereto. The crosspoint cells, the size of which is defined solely by the respective widths of the electrodes, thus arise at the crossover points. However, it is also possible for the bottom electrodes not to be covered completely with the compound, but rather only at the locations where the crosspoint cell arises. This becomes possible either by means of the integration method, as is described later, or by means of a direct patterning of the compound.

In the case of this crosspoint construction, it is readily possible to provide a plurality of planes of such memory cells in memory cell arrays stacked one above another. Each “plane” of such a memory cell array then contains the associated top and bottom electrodes and also the compound situated in between. It is possible for one electrode to be jointly utilized by two planes, for example, the top electrode of the first plane may simultaneously serve as the bottom electrode of the overlying second plane. A prerequisite is, of course, that this electrode includes at least two suitable layers. An insulating layer may also be introduced between two planes, depending on the requirements.

Very high integration densities can thus be achieved, the so-called “bit size” being of the order of magnitude of “4 F²/n” where n is the number of individual planes of memory cell arrays that are stacked one above another and “F” denotes the width (smallest possible structure of the technology used).

As an alternative to the abovementioned crosspoint concept, it is possible to produce contact holes directly above the bottom electrode—for example, in an insulating layer—and then to form the compound in the contact hole directly on the bottom electrode. The size of the cell is then defined by the size of the contact hole (so-called “via concept”).

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1A illustrates a via concept in which the size of the cell is precisely defined and is not dependent on the size (that is to say width) of the interconnects that cross one another.

FIG. 1B illustrates an integration concept in which a cell size of approximately 4 F² can be achieved (crosspoint concept).

FIG. 1C illustrates a further integration concept with planes stacked one above another and a bit size of approximately 4 F²/n; where n=number of planes.

FIGS. 2 to 10 illustrate steps that lead to the integration concept in accordance with FIG. 1A.

FIGS. 11 to 22 illustrate steps that lead to the integration concept in accordance with FIG. 1B.

FIGS. 23 to 27 illustrate steps that lead to an alternative crosspoint construction, the compound being produced only in the region of the crosspoint cell (and not along an entire electrode as in FIG. 14).

FIGS. 28 to 44 illustrate a detailed illustration of the method according to one embodiment of the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

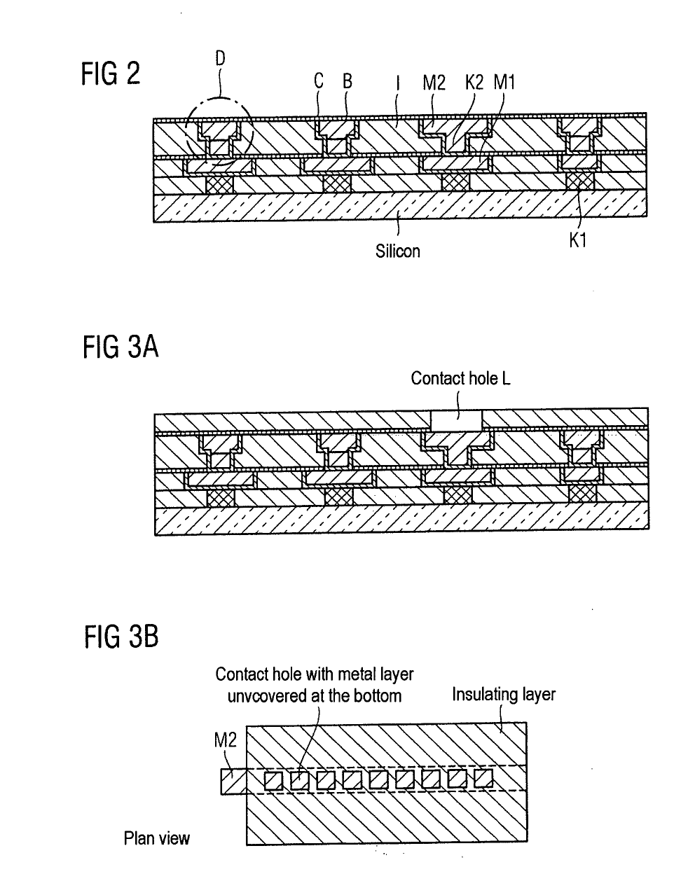

FIG. 2 illustrates a silicon wafer, in the case of which the FEOL processes have been concluded and the layers depicted there have subsequently been applied. K1 designates a contact (contact hole filled with a conductor material, in one case made of tungsten), B designates layer 1 of the bottom electrode (that is to say U1 according to the previous sketch), C designates a capping layer, I designates an insulating layer and M designates an interconnect. Interconnects M1 or M2 include for example layer 1 (=B, for example, tantalum) and layer 2 (for example, copper).

K2 designates a contact, that is to say a contact hole which has been filled with the same materials as the interconnect M2. This is effected for example, in the dual damascene process, in which firstly layer 1 is deposited simultaneously into contact holes K2 and trenches and then layer 2 is deposited. The filled trenches then form the interconnects or electrodes. Layer 1 may in one case also include two or more layers (for example, tantalum nitride and tantalum).

The capping layer C is in one case Si, TiNSi, SiON, SiO, SiC, SiN, SiCN and any desired combination of these layers or materials.

D is either a combination of two contacts lying one on top of another or a contact and a pad in order to produce the electrical contact with the substrate and/or with the upper planes.

Even though the substrate in FIG. 2 has been designated as a silicon wafer, the substrate may also be one of the alternatives described earlier. An insulating layer (in one case silicon oxide), is then applied on such a substrate as described in FIG. 2.

FIG. 3 illustrates how the contact holes L are opened in said insulating layer by means of photolithography and etching along the interconnects in order to attain the construction as illustrated in FIG. 3A. The capping layer under the contact holes is likewise opened, so that for example the copper surface becomes free there. After the copper surface has been uncovered, the organic material can be applied in order to produce the compound.

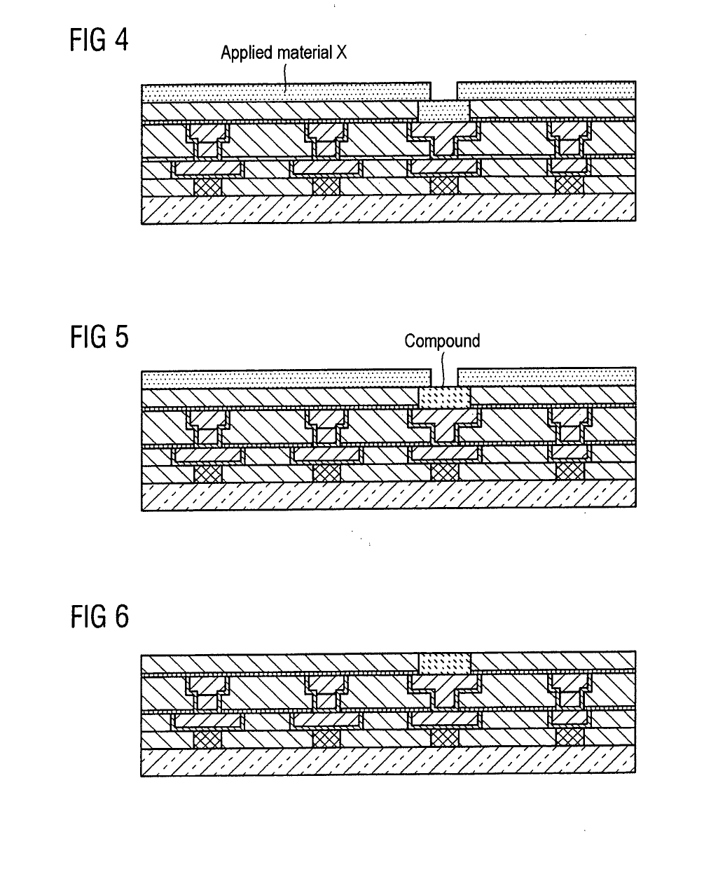

FIG. 4 illustrates how the organic material, TCNQ in the specific case, is deposited onto the substrate surface (FIG. 4 relates to vacuum vapor deposition). The deposition of TCNQ may be effected by means of a vacuum process such as, for example, vapor deposition or by means of a solution of TCNQ. The precise parameters for how the organic material is applied to the electrode are described in the general part of the application. If the organic material from the solvent is brought into contact with the electrode, the desired compound forms selectively only above the electrode. If the organic material is deposited onto the electrode by means of vapor deposition, however, a thermal treatment has to be effected in order to produce the compound.

FIG. 5 illustrates how the compound is formed selectively in the contact holes either after the thermal treatment, if the organic material is vapor-deposited, or directly after the contacting of the electrode with the solution of the organic material. The insulating layer does not react with TCNQ.

FIG. 6 illustrates the substrate surface after rinsing with a solvent, such as acetone for example. The solvent removes the excess organic material that has not formed a compound. For this purpose, the substrate surface may be rinsed by dipping, spraying or spinning (in the spin coater). As a result, the dimensions of the cell are clearly defined and adjacent cells are insulated from one another by the insulating layer.

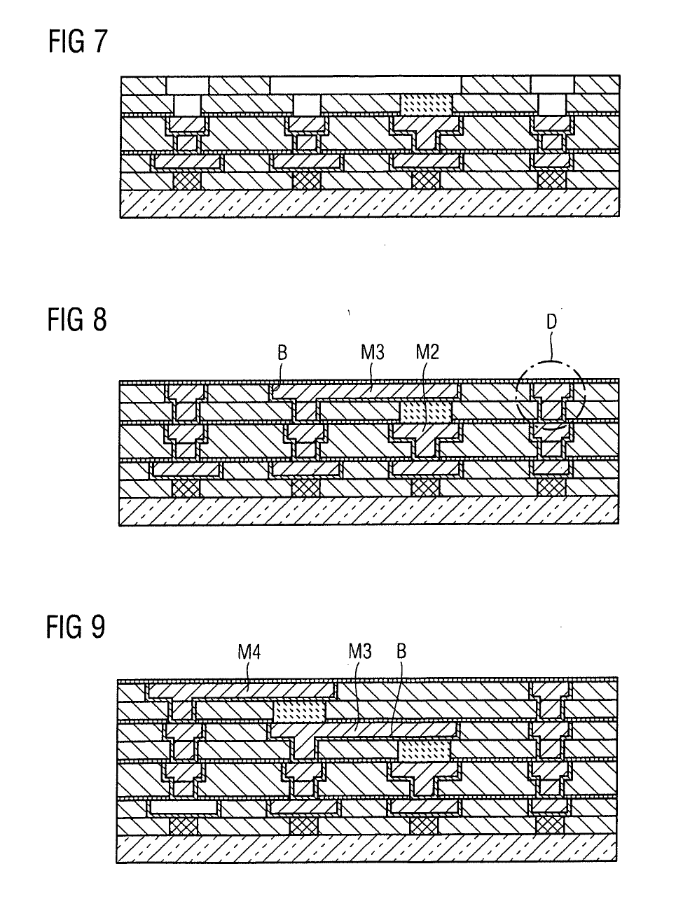

FIG. 7 illustrates how a further layer of insulating layer can be applied, and in one case how the—newly arisen—substrate surface can be patterned for the production of the interconnects. This may be done using customary lithographic techniques and subsequent etching. The patterning is in one case effected by means of the customary dual CU damascene patterning. In this case, the trenches and contact holes are simultaneously filled with the materials of the corresponding layers and subsequently ground. After the application of the capping layer, the construction illustrated in FIG. 8 is obtained.

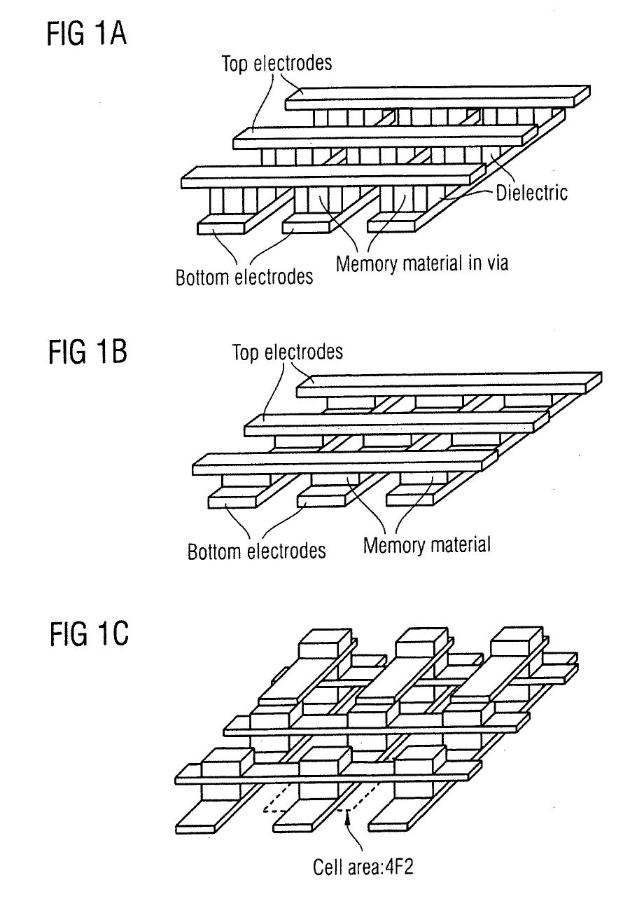

The layer B is in one case made of tantalum nitride or is a combination of tantalum and tantalum nitride. The tracks M2 and M3 produced in FIG. 8 are perpendicular to one another. The structure illustrated in FIG. 1A is thereby obtained (with M2 as bottom electrode and M3 as top electrode).

A construction illustrated in FIG. 9 is obtained by applying a further layer of the insulating layer and repeating the steps that have been elucidated in FIGS. 3 to 8. The interconnect M3 may serve both as top electrode for the bottom cell and as bottom electrode for the top cell. M4 is the top electrode of the top cell and is perpendicular to M3. The construction illustrated in FIG. 9 is similar to FIG. 1C, with the difference that FIG. 1C illustrates a stack (construction having more than one cell plane) on the basis of the crosspoint concept and FIG. 9 illustrates a stack on the basis of the via concept. With the latter construction, the cell size is precisely defined and that the lateral insulation of the individual memory cells by the insulating layer prevents crosstalk of the adjacent cells. With this construction, however, the bit size is more than 4 F²/n (lower integration density).

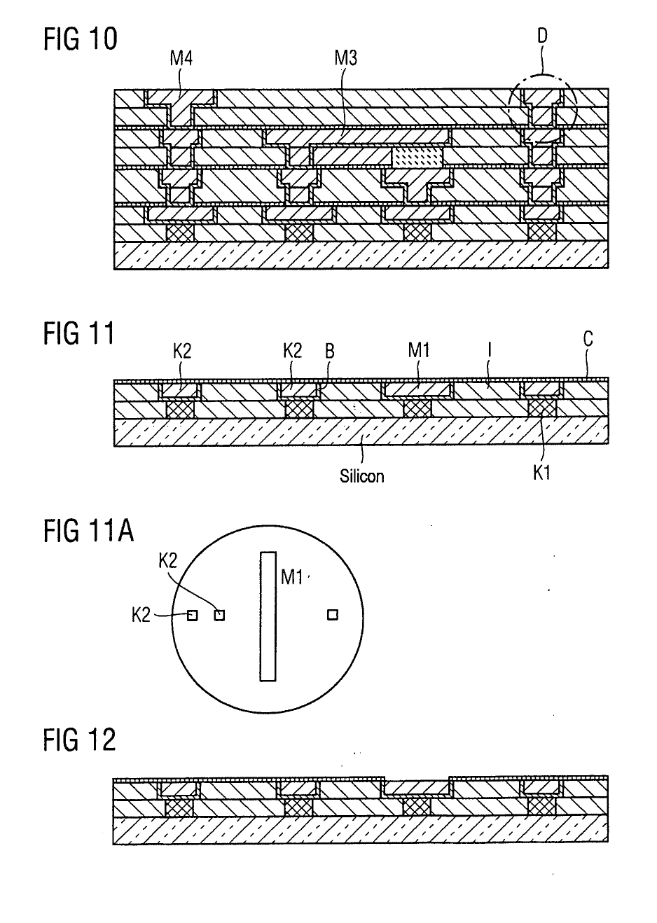

FIG. 10 illustrates how further processing would have to be effected in order to provide an insulating layer between the first and second cell planes (that is to say that M3 would then no longer serve as a common electrode for two cells). After the application of the capping layer to the substrate in accordance with FIG. 10, processing would be effected according to FIGS. 3 to 8 in order to produce the next cell plane.

FIGS. 11 to 19 illustrate an integration concept for the semiconductor arrangement according to one embodiment of the present invention, the integration concept enabling a bit size of 4 F²/n.

FIG. 11 illustrates a substrate similar to that in FIG. 2. FIG. 2 and FIG. 11 make it clear that the substrate may be different. It is also possible to start with a substrate as illustrated in FIG. 2. FIG. 11A illustrates the plan view of the structure illustrated in FIG. 11.

As already described in FIG. 2, the substrate may be either a silicon wafer or silicon, germanium, gallium arsenide, gallium nitride; an arbitrary material containing an arbitrary compound of silicon, germanium or gallium; a polymer, ceramic, glass or metal.

As illustrated in FIG. 12, the capping layer C is opened by means of photolithography and etching in order to uncover the interconnects. The compound is intended to be formed later above said interconnects.

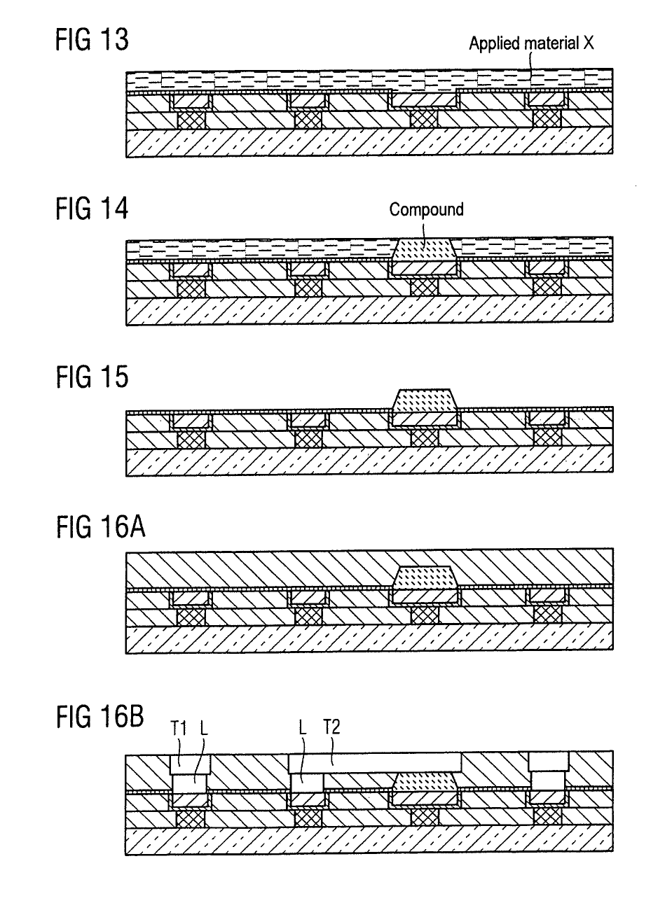

FIG. 13 illustrates the construction after the deposition of the organic material X. The compound has not yet formed above the interconnect since the organic material has been vapor-deposited by means of a vacuum method. It is only after the substrate obtained in this way has been subjected to a thermal treatment that the compound forms above the interconnect. Since the compound between the metal, for example, copper, and the organic material is formed selectively only above the metal (FIG. 14), the opening in the capping layer may be larger than the width of the interconnect M1, the intention being also to take account of the overlay tolerances during the photolithography. The organic material may, as described above, be applied either by means of a vacuum process or by treatment with a solvent. If the organic material in the solvent is applied to the substrate, the structure depicted in FIG. 13 is obviated.

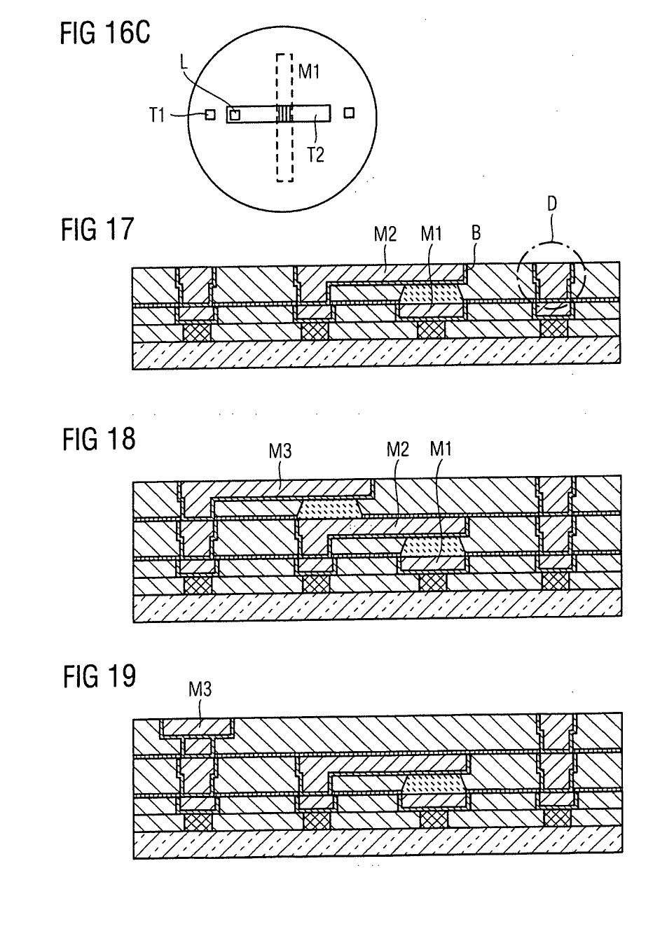

The substrate is then rinsed with acetone, for example, in order to remove the excess organic material. The result of this step is described in FIG. 15. The trapezoidal structure of the compound is only schematic. Once the compound has formed over the entire length of the interconnect, a layer of insulation is applied and ground, for example, by means of CMP, in order to attain the construction depicted in FIG. 16A.

Contact holes for the contacts and also trenches for the interconnects can then be opened according to FIG. 16B using customary lithography and etching techniques. The interconnects which are now to be formed run transversely with respect to the interconnects depicted as M1 in FIG. 11. The patterning may be effected for example by means of dual Cu damascene patterning. In FIG. 16B, T1 is either a contact hole or a trench for a pad and L is a contact hole. T2 is a trench for an interconnect which must exhibit an expansion at least by the magnitude of the alignment tolerances above the contact hole. FIG. 16C illustrates the plan view of the structure illustrated in FIG. 16B. The hatched region illustrates the area where the compound formed becomes visible through the trench T2 produced.

As illustrated in FIG. 17, the trenches and holes can be filled and planarized by means of the dual Cu damascene technique. Here B is layer 1 of the top electrode, which in some cases includes tantalum nitride or a combination of tantalum and tantalum nitride. Copper in one case forms layer 2 of the top electrode. In FIG. 17, the tracks M1 and M2 are perpendicular to one another. Consequently, the memory cells are defined everywhere at the locations where the tracks cross one another. D is either a combination of two contacts K or of a contact and a pad, and serves for wiring the different interconnects in different planes with the substrate.

The construction illustrated in FIG. 18 is obtained by applying a further capping layer and subsequently repeating the steps illustrated in FIGS. 12 to 17. In this FIG. 8, the interconnect M2 (including for example Ta and Cu or Ta, TaN and Cu) may serve both as top electrode for the bottom cell and as bottom electrode for the top cell. M3 is the top electrode of the top cell and is perpendicular to M2. The construction illustrated in FIG. 18 corresponds to FIG. 1C.

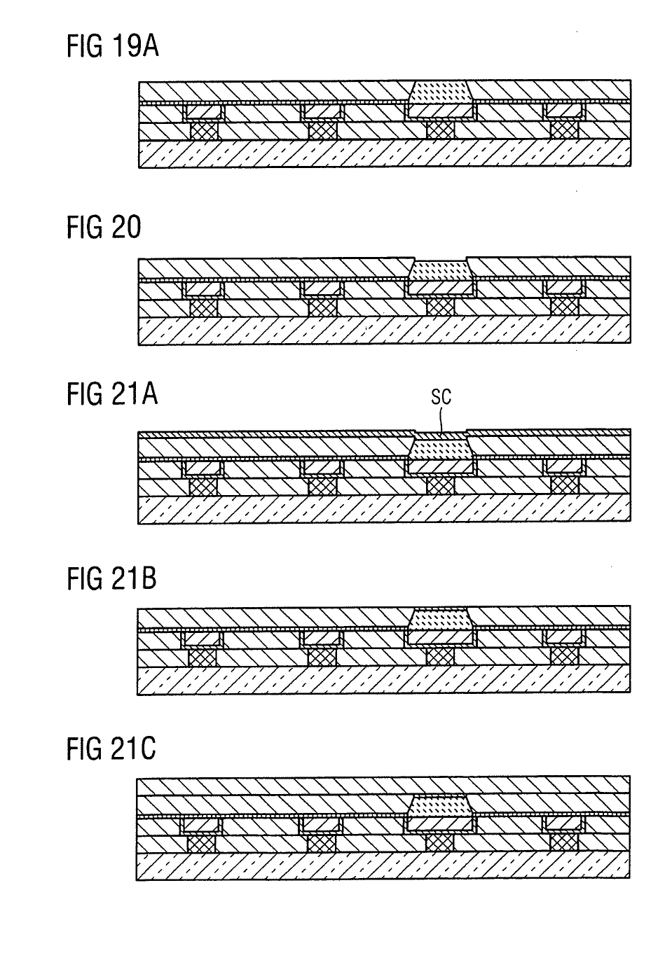

As illustrated in FIG. 19, an interconnect, such as M2 for example, need not necessarily serve as an electrode for top and bottom cells. It is also possible for a compound not to be formed on the interconnect M2, but rather for a capping layer and then an insulating layer to be applied and firstly the interconnect plane M3 to be produced and contact-connected. After the application of a further capping layer, the procedure may continue according to FIG. 12. In such a construction, each interconnect serves either only as top electrode or as bottom electrode, that is to say no common electrodes for two cell planes lying one above another.

With this concept, a bit size of 4 F²/n can be achieved. However, the organic material is deposited over the entire interconnect, so that the cells are not isolated from one another by a dielectric. This has the effect that the cells are isolated from one another by a dielectric only in one direction (for example, x direction), but not in the y direction, that is to say along the interconnect.

The embodiment below illustrates an alternative to the production of the integration concept in accordance with FIGS. 11 to 18 and 19. In this embodiment, after the step illustrated in FIG. 15, an insulating layer is deposited and ground back to the level of the compound formed, which produces the construction illustrated in FIG. 19A. Afterward, the substrate is etched by means of argon plasma, for example, over approximately 20 s to 5 min. In this case, the compound is etched significantly more rapidly than the insulating layer, so that a height difference is produced between the compound layer and the insulation, as illustrated in FIG. 20. This selective etching may also be effected wet-chemically, for example by treating the substrate with a mixture of ammonia and a solvent, such as dimethylformamide, for example. The purpose of this step is to create space for a further protective layer SC, which is deposited onto the compound. Said protective layer is firstly deposited over the whole area, as is illustrated in FIG. 21A, but after chemical mechanical planarization (CMP) said layer is maintained only above the interconnect M1 or above the compound (FIG. 21B). Said layer in one case includes the same material as the top electrode or layer 1 of the top electrode if the top electrode includes a plurality of layers. However, it may also include one of the other electrode materials already mentioned. A further insulating layer is subsequently applied in order to attain the construction as illustrated in FIG. 21C.

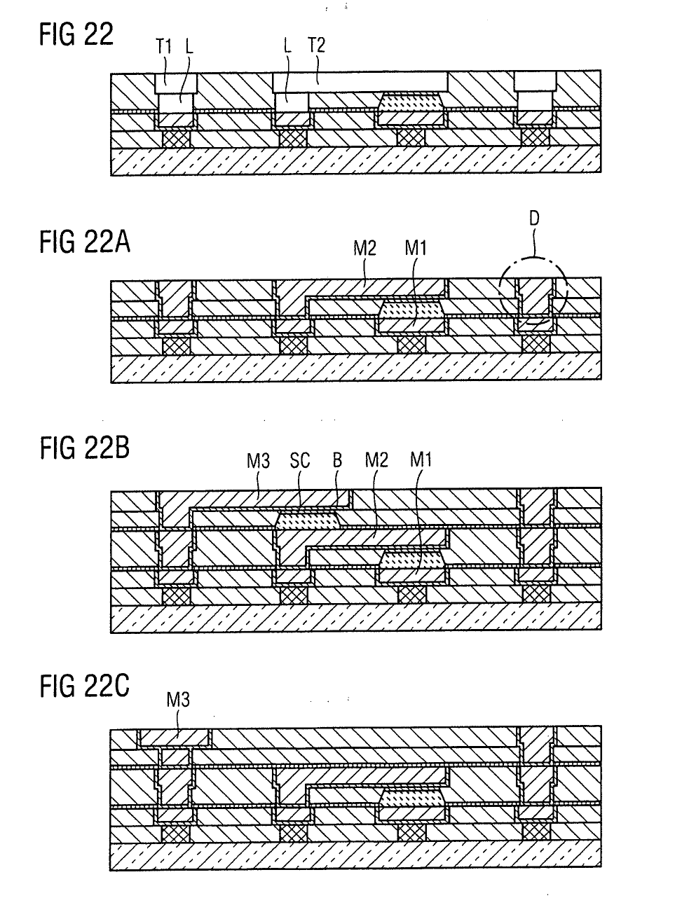

As illustrated in FIG. 22, contact holes for the contacts and trenches for the interconnects or pads can be opened by means of customary lithography and etching techniques, such as for example, the dual damascene technique, as already described in FIG. 16B. After deposition and grinding of the electrode materials, the structure similar to that in FIG. 17 is obtained, with the difference that in the present case (FIG. 22A) the layer B above the compound is somewhat thicker. For further construction, a capping layer may again be applied and then the procedure may continue according to FIG. 15 and arrive at a construction as illustrated for example, in FIG. 18 or 22B. If the same material as for the layer B is used as the protective layer SC, the layer B is thicker in FIG. 22B than in FIG. 18. If different materials are used for the layers B and SC, two layers are obtained, as illustrated in FIG. 22B. The construction depicted in FIG. 22B corresponds to the construction of FIG. 18 with an additional SC layer.

The integration concept in accordance with FIGS. 19A to 22B or 22C differs from the method illustrated in FIGS. 11A to 19 by virtue of the application of the protective layer selectively to the compound. In this case, the compound is protected by said protective layer, for example, during the etching processes.

The embodiment below shows an alternative to the production of an integration concept for the semiconductor arrangement according to one embodiment of the invention. In this embodiment, an insulating layer is deposited onto the first interconnect, which also represents the bottom electrode for the cell according to one embodiment of the invention, and only then is the compound formed (that is to say that the step carried out in FIG. 16A is effected before the step carried out in FIG. 13 or 14). This concept results in a reduction of the process complexity.

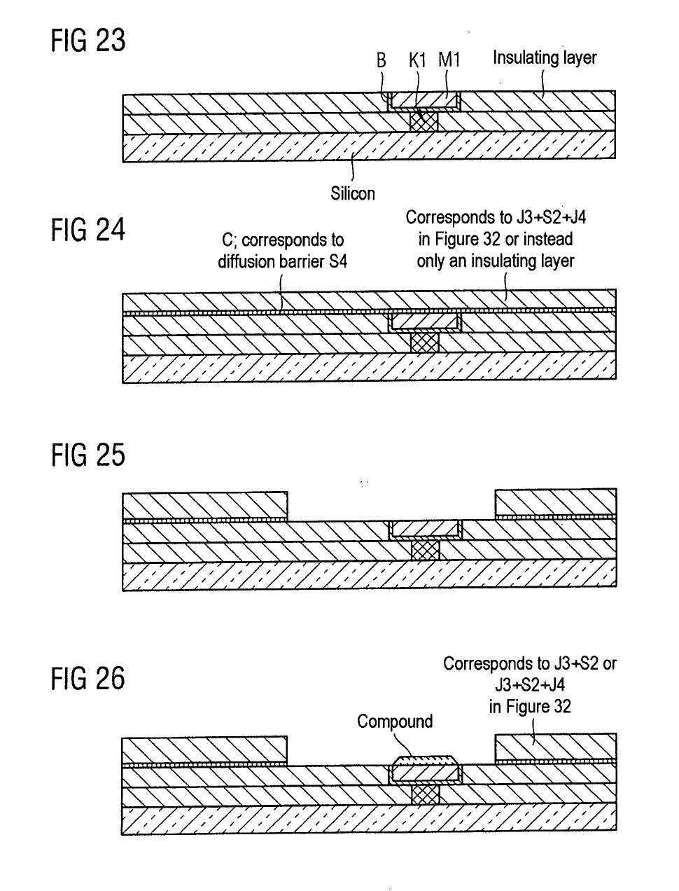

The substrate in FIG. 23, which approximately corresponds to FIGS. 2 and 11A, has applied to it firstly a capping layer C (cap) and then an insulating layer, in one case made of silicon dioxide, in order to attain the construction as illustrated in FIG. 24. The trenches for the later interconnects are subsequently opened into said insulating layer by means of photolithography and etching, as illustrated in FIG. 25. The capping layer under the trenches is likewise opened, so that the copper surface becomes free at the locations where the (upper) trenches cross the (underlying) copper tracks.

Onto this substrate surface, the organic material is then deposited onto the copper surface either by means of a vacuum process or by treatment with a solution of the organic material, and the compound is formed. If the deposition of the organic material is carried out by means of a vacuum technique, a thermal treatment has to be effected, which may be carried out for example, on a hot plate or in a furnace, so that the compound is formed selectively above copper, as illustrated in FIG. 26, since the insulating layer does not react with the organic material.

The substrate surface is then rinsed with a solvent, such as acetone for example. This may be effected by dipping, spraying or in the spin coater. Consequently, the dimensions of the cell are clearly defined and adjacent cells are isolated from one another by the insulating layer, as illustrated in FIG. 26. In this case, the compound is not formed along the entire interconnects, but rather only locally at the crossover points.

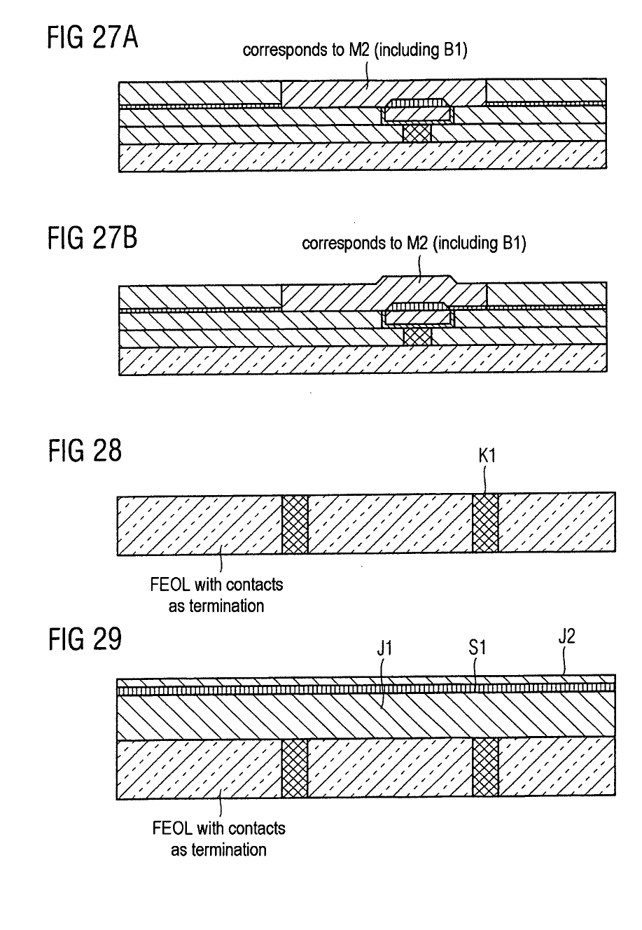

The trenches are subsequently filled with the electrode material or materials (if the electrode includes more than one layer). Afterward, grinding may optionally be effected. FIGS. 27A and 27B illustrate the two possibilities, that is with and without grinding (polishing) of the top electrode.

The construction essentially corresponding to the integration concept illustrated in FIG. 1C is obtained by applying a capping layer and subsequently repeating the steps illustrated in FIGS. 24 to 27.

With this integration concept, an exact definition of the cell dimensions of the memory cells is possible, so that crosstalk between the cells is largely prevented. It is thus possible to achieve an integration concept having the bit size 4 F²/n.

It should be noted that the individual layers disclosed in the description may include a plurality of layers if this is desirable. The structures illustrated in FIGS. 28 to 36 elucidate in greater detail how the individual layers can be constructed.

FIG. 28 illustrates the substructure in the case of which FEOL and MOL processes are carried out and provided with contacts K1 as termination. The contacts K1 in one case include tungsten.

The construction according to FIG. 28 is only an alternative which may serve as a substrate for the intended construction with the memory cells according to one embodiment of the invention.

An insulating layer (J1), in one case SiO, is applied to the substrate. If appropriate, the insulating layer J1 may have applied to it additionally a Cu CMP stop layer S1 made of for example, silicon carbide (SiC) and, for the protection thereof during the lithography process, additionally a further layer J2, which in one case again includes SiO. The state after the deposition of the layers J1, S1 and J2 is illustrated in FIG. 29.

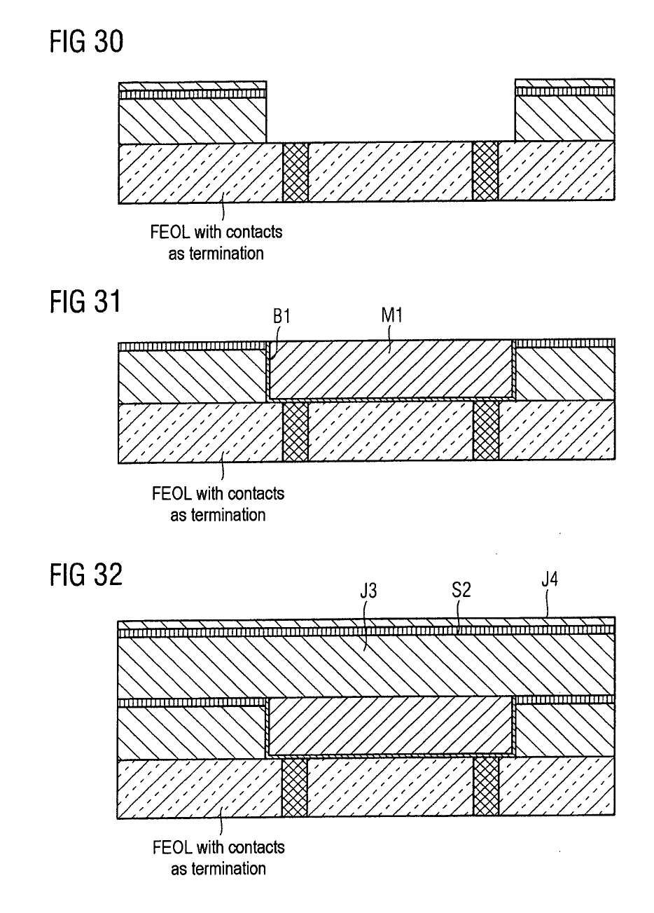

The layers J1, S1 and J2 are patterned by means of photolithography and RIE (reactive ion etching), as a result of which the contacts K1 are uncovered, as illustrated in FIG. 30.

The two-layered bottom electrode is applied by means of a standard Cu damascene process. Firstly, the barrier layer B1 is deposited, which includes customary barrier materials or a combination thereof. After the application of the Cu seed layer, copper is deposited by means of an ECD (electrochemical deposition) process and, under certain circumstances, is subsequently subjected to thermal aftertreatment. This is followed by the chemical mechanical polishing of copper and of the barrier layer, a high selectivity between the copper and the barrier CMP being necessary. The CMP stop layer S1 is necessary in order to ensure a selective barrier CMP process. The CMP process must otherwise be carried out nonselectively. The structure thus obtained is illustrated in FIG. 31.

The layer of the interconnect (M1) that has been generated in this way may have applied to it a copper diffusion barrier S4, in one case made of HDP (high density plasma) S1 and N (not illustrated in FIGS. 31 and 32, but later in FIG. 41). An insulating layer J3, in one case made of SiO, is then applied. If appropriate, the dielectric layer may have applied to it a CMP stop layer S2 made of for example, SiC, and for the protection thereof during the lithography process, a further protective layer J4 may additionally be deposited thereon. The protective layer J4 likewise includes SiO. The structure thus obtained is illustrated in FIG. 32.

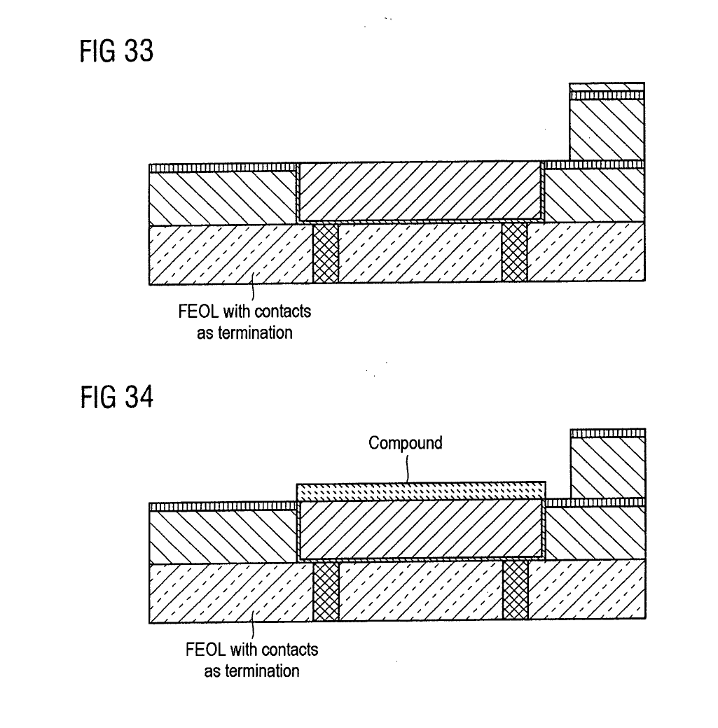

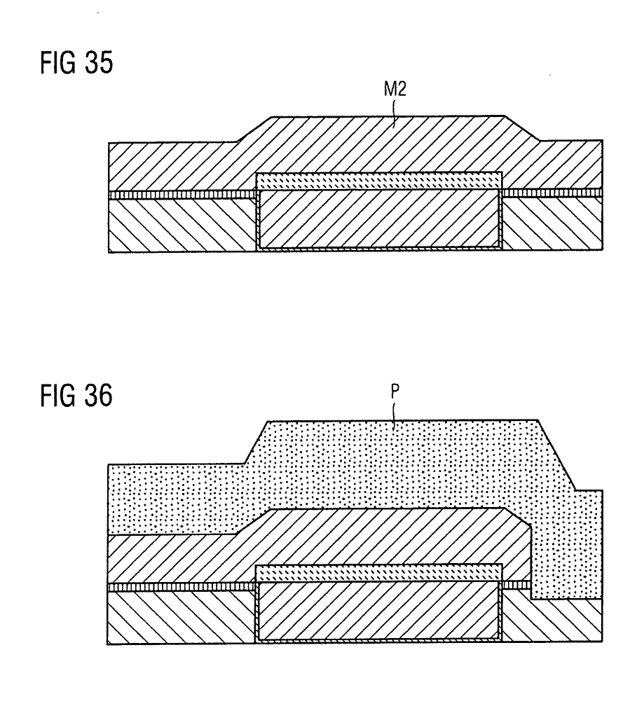

Trenches are produced in a subsequent step, which trenches in this plane are at an angle of 90° with respect to the M1 tracks in the preceding plane. The trenches produced are illustrated in FIG. 33. The layers S2 and J3 and, if appropriate J4 are patterned by means of lithography and RIE (reactive ion etching), as a result of which the M1 tracks are partly uncovered. The organic material is then deposited on the uncovered locations of the M1 tracks by a method as described in the previous embodiments, in order to achieve the compound according to one embodiment of the invention. The structure thus produced is illustrated in FIG. 34. It corresponds to FIG. 26, with the difference that more details of the layers are illustrated in FIG. 34. The procedure may subsequently continue for example, as in FIG. 27A. After the application of the required number of planes according to FIGS. 24-27A, a final (topmost) interconnect M2 may be constructed, for example, by means of whole-area deposition of suitable electrode materials. Customary materials such as for example, Ti/AlCu/TiN may be used as electrode materials in this case. The structure obtained is illustrated in FIG. 35. The patterning here is by means of an RIE process.

As the last layer, a standard passivation layer P (for example, SiO, SiN, SiON, SiC and arbitrary combinations of these layers) is deposited and the bonding pads are opened. The structure obtained is illustrated in FIG. 36.

The subsequent figures illustrate a variant of the concept described in FIGS. 11 to 19, a detailed layer construction being illustrated below.

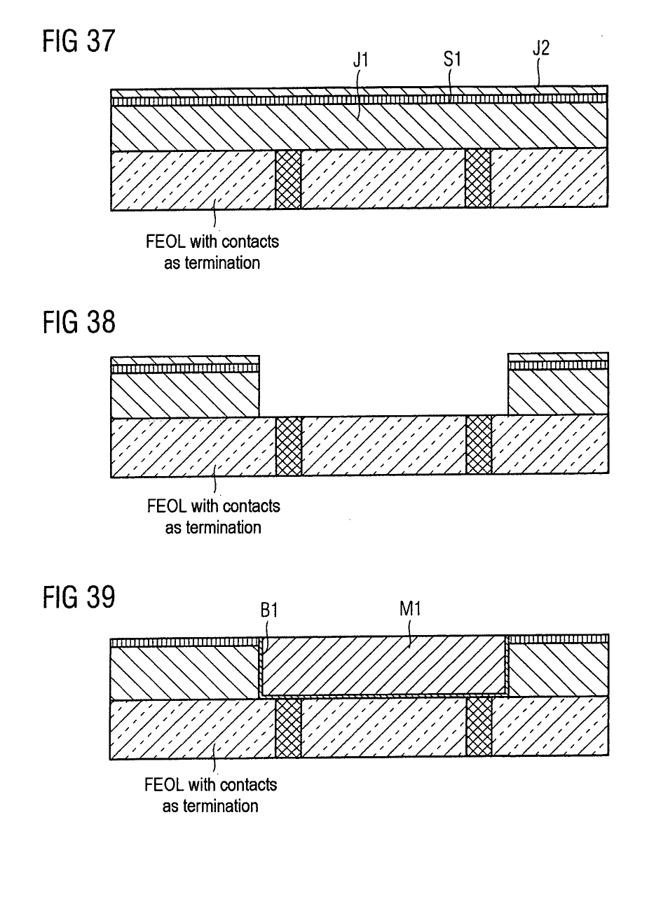

An insulating layer J1, in one case made of SiO, is applied to the substrate. If appropriate, the insulating layer J1 may have deposited onto it additionally a Cu CMP stop layer S1, for example, made of SiC, and, for the protection thereof during the lithography process, additionally a protective layer J2, in one case again made of SiO. The structure thus obtained corresponds to the arrangement illustrated in FIG. 37. The dielectric is patterned in order to attain a construction as illustrated in FIG. 38.

The interconnect forming the bottom electrode is deposited by means of a standard Cu damascene process. The bottom electrode includes at least two layers, as described above. In order to produce the interconnect M1, the barrier layer B1 made of customary barrier materials or a combination thereof is deposited. After application of the Cu seed layer, Cu is deposited by means of an ECD (electrochemical deposition) process and, under certain circumstances, is subsequently subjected to thermal aftertreatment. This is followed by the chemical mechanical polishing of the copper layer and the barrier layer, a high selectivity between the copper and barrier CMP being necessary. The construction is illustrated in FIG. 39.

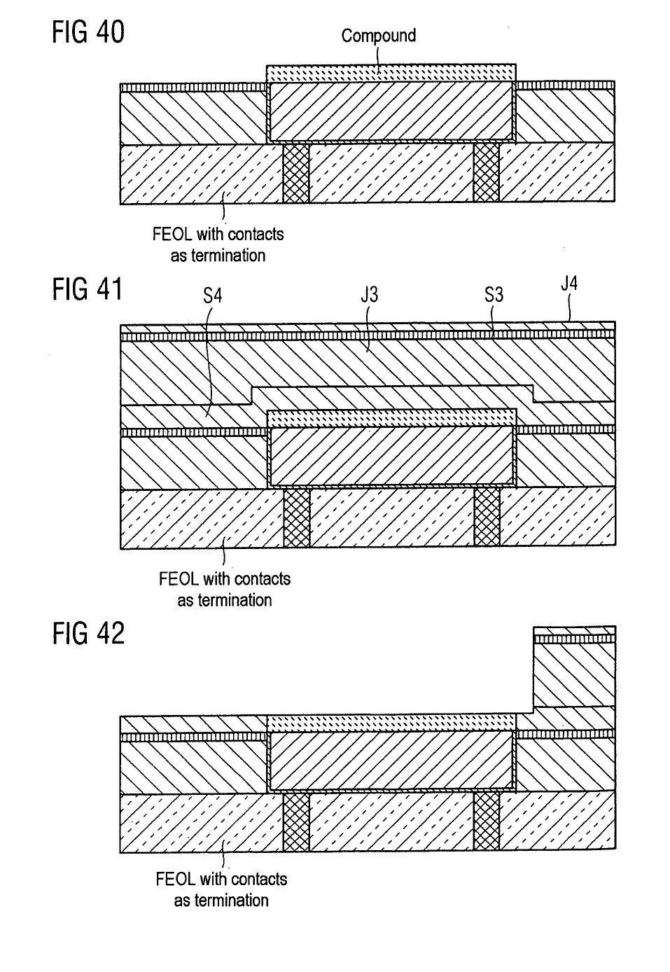

The organic material can then be deposited selectively into the interconnect, as already explained for FIGS. 13-15. The structure thus obtained is illustrated in FIG. 40. The deposition of the organic material may be effected as described in FIG. 13. A layer including, for example, HDP (high density plasma) SiN may subsequently be deposited. This layer serves as a copper diffusion barrier S4. A further insulating layer J3, which includes in one case SiO, may then be deposited onto this layer. If appropriate, a CMP stop layer S3 including for example, SiC may be deposited onto the dielectric layer. In order to protect the S3 layer during the lithography process steps, a further protective layer J4, in one case also made of SiO, may additionally be deposited. The structure thus obtained is illustrated in FIG. 41.

The next step is to generate the trenches for the interconnects for producing the top electrodes. The structure after etching is illustrated in FIG. 42. The trenches to be generated are at an angle of 90° with respect to the M1 tracks in the preceding planes.

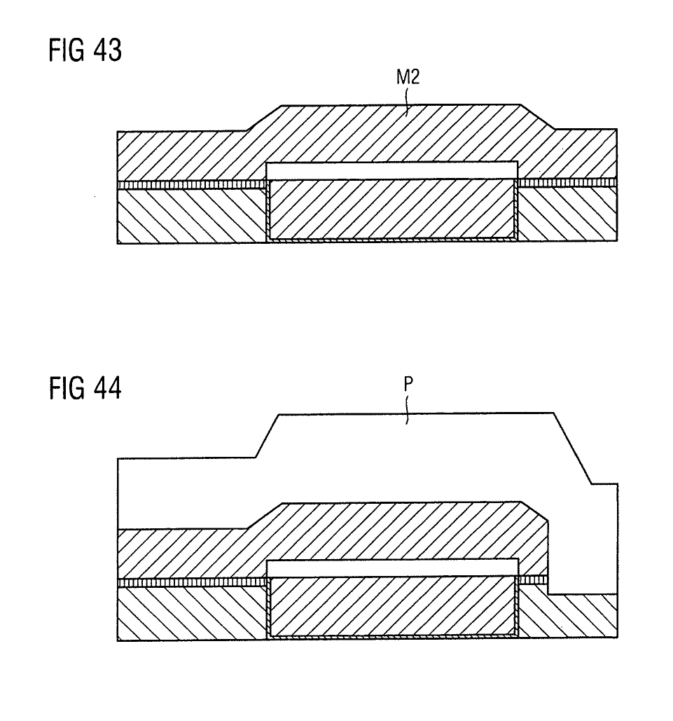

After application of the required number of planes, the final (topmost) interconnect M2 may be constructed, as illustrated in FIG. 43. After the patterning thereof, a passivation layer P is deposited as the last layer in order to attain the construction illustrated in FIG. 44. The passivation layer P may be SiO, SiN, SiON or SiC and an arbitrary combination of these layers.

In the case of the last plane, the interconnect M1 is treated after the CMP process with the organic material arranged thereon, the compound between the organic material and the metal being produced selectively on the copper tracks. A final interconnect M2, serving as an electrode, is constructed by means of a whole-area deposition of suitable electrode materials, as already described in FIG. 34.

Instead of silicon dioxide, the so-called “low k” material may also be used as the insulating layer I or J. In this case, k denotes the dielectric constant. Insulating layers which permit a higher signal speed owing to the lower k values in comparison with silicon dioxide are involved in this case.

Examples of such materials are:

polymers such as polyimides, polyquinolines, polyquinoxalines, polybenzoxazoles, polyimidazoles, aromatic polyethers, polyarylenes including the commercial dielectric SILK, polynorbornenes; furthermore copolymers of the materials mentioned; porous silicon-containing materials, porous organic materials (porous polymers), porous inorganic-organic materials.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1-44. (canceled)

45. A semiconductor arrangement comprising at least one nonvolatile memory cell with a first electrode comprising at least two layers and an organic material, the organic material forming a compound with that layer of the first electrode which is in direct contact, the semiconductor arrangement produced by:
providing a first electrode comprising at least two layers and a layer of the first electrode forms a compound with an organic material;
contacting the first electrode with an organic material in order to form a compound; and
forming a second electrode on the compound formed.

46. The semiconductor arrangement of claim 45, wherein the organic material has at least one of the following materials or compounds: sulfur, selenium and tellurium either in pure or in bonded form in particular as organocompounds of sulfur, selenium and tellurium, and sulfur-, selenium- and tellurium-containing oligomers or polymers, and one of the following compounds: 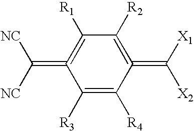 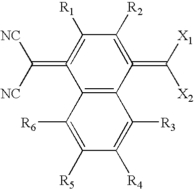 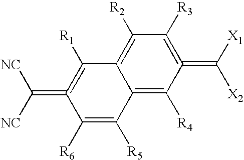 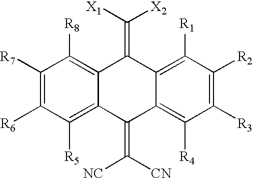 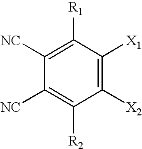 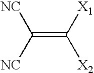 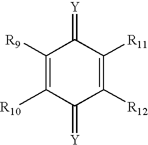 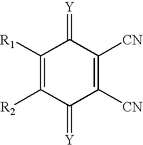 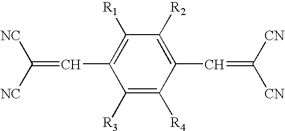 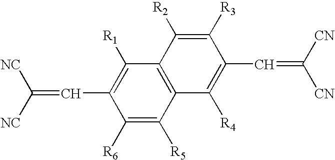 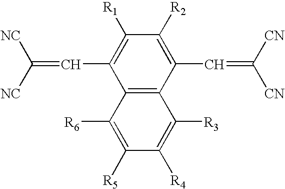 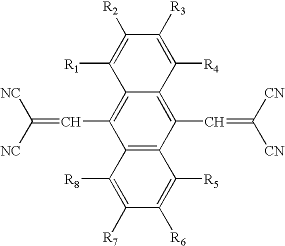 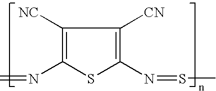 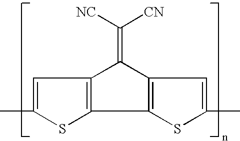 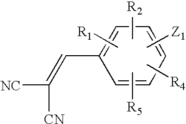 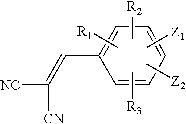 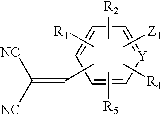 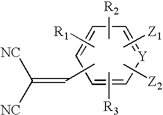 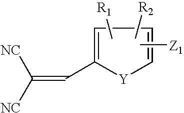 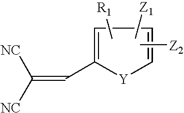
where R₁, R₂, R₃, R₄, R₅, R₆, R₇ and R₈, independently of one another, have the following meaning:
H, F, Cl, Br, I (iodine), alkyl, alkenyl, alkynyl, O-alkyl, O-alkenyl, O-alkynyl, S-alkyl, S-alkenyl, S-alkynyl, OH, SH, aryl, heteroaryl, O-aryl, S-aryl, NH-aryl, O-heteroaryl, S-heteroaryl, CN, NO₂, —(CF₂)ₙ—CF₃, —CF((CF₂)ₙCF₃)₂, -Q-(CF₂)ₙ—CF₃, —CF(CF₃)₂, —C(CF₃)₃ and 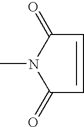 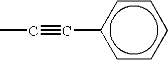 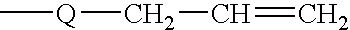 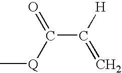 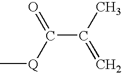 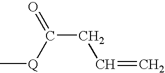 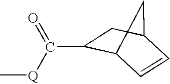 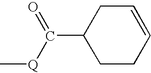 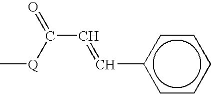 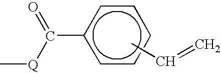 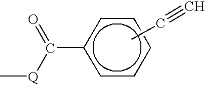 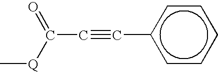 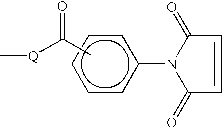 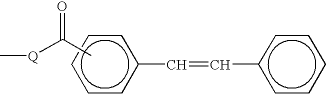 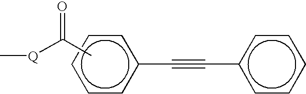
n: n=0 to 10
Q: —O—, —S—
R₉, R₁₀, R₁₁, R₁₂ may, independently of one another, be:
F, Cl, Br, I, CN, NO₂
R₁₃, R₁₄, R₁₅, R₁₆, R₁₇ may, independently of one another, be:
H, F, Cl, Br, I, CN, NO₂
X₁ and X₂ may, independently of one another, be:
CN 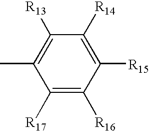 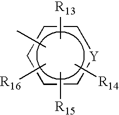 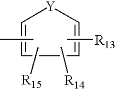 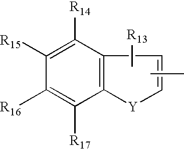
Y is: O, S, Se
and Z₁ and Z₂, independently of one another, are: CN, NO₂.

47. The semiconductor arrangement of claim 45, wherein the organic material is an electron acceptor.

48. The semiconductor arrangement of claim 47, wherein the electron acceptor has electron-attracting atoms or groups which are selected from: —Cl, —F, —Br, —I, —CN, —CO—, —NO₂.

49. The semiconductor arrangement of claim 45, wherein the organic material forms a charge transfer complex with the bottom electrode.

50. The semiconductor arrangement of claim 45, wherein that layer of the first electrode which is in contact with the organic material contains one of copper and silver.

51. The semiconductor arrangement of claim 45, wherein the organic material is present in a film thickness of between 30 and 1000 nm.

52. The semiconductor arrangement of claim 45, wherein the cell is scalable up to an area of 40 nm².

53. The semiconductor arrangement of claim 45, wherein that layer of the first electrode which is not in contact with the organic material is titanium (Ti), titanium nitride (TiN), tantalum (Ta), tantalum nitride (TaN), tungsten (W), TiW, TaW, WN, WCN, IrO, RuO, SrRuO, or a combination of said layers and/or materials and, if appropriate, is additionally provided with a layer made of Si, TiNSi, SiON, SiO, SiC or SiCN.

54. The semiconductor arrangement of claim 45, wherein the second electrode is made of aluminum, copper, AlCu, AlSiCu, silver (Ag), titanium (Ti), titanium nitride (TiN), tantalum (Ta), tantalum nitride (TaN), tungsten (W), TiW, TaW, WN, WCN, IrO, RuO, SrRuO, or a combination of said layers and/or materials and, if appropriate, is additionally provided with a layer made of Si, TiNSi, SiON, SiO, SiC or SiCN.

55. The semiconductor arrangement of claim 45, wherein the cell can be switched between an ON state and an OFF state.

56. The semiconductor of claim 55, wherein the ON and OFF states have different electrical resistances.

57. The semiconductor arrangement of claim 56, wherein the ratio between the ON and OFF states is more than 66.

58. A method for producing a nonvolatile memory cell comprising:
providing a first electrode comprising at least two layers and an organic material;
forming a compound with the organic material and a layer of the first electrode;
contacting the electrode with an organic material in order to form a compound; and
forming a second electrode on the compound formed.

59. The method of claim 58, further comprising vapor depositing the organic material onto the electrode under reduced pressure.

60. The method of claim 58, further comprising dissolving the organic material in a solvent in the process of contacting the first electrode.

61. The method of claim 58, further comprising subjecting the organic material to a thermal treatment prior to forming the second electrode.

62. The method of claim 58, further comprising rinsing the excess organic material with a solvent prior to forming the second electrode.

63. The method of claim 59, wherein the organic material is vapor-deposited at a pressure of between 0.00001 and 200 mbar.

64. The method of claim 58, wherein the contacting of the organic material takes place at a substrate temperature of between −50° C. and 150° C.

65. The method of claim 58, further comprising mixing the organic material in the gas phase with a carrier gas.

66. The method of claim 58, further comprising treating the compound formed with an aftertreatment reagent prior to providing the second electrode.

67. The method of claim 66, wherein the aftertreatment reagent is selected from a group comprising: amines, amides, ethers, ketones, carboxylic acids, thioethers, esters, aromatics, heteroaromatics, alcohols and sulphur- and selenium-containing compounds.

68. The method of claim 67, wherein the sulphur-containing compounds are selected from a group comprising: sulphur hetercyclic compounds, —SO— containing compounds and thiols.

69. The method of claim 66, wherein the aftertreatment reagent is selected from the group comprising: diethylamine, triethylamine, dimethylaniline, cyclohexylamine, diphenylamine, dimethylformamide, dimethylacetamide, dimethyl sulfoxide, acetone, diethylketone, diphenylketone, phenyl benzoate, benzofuran, N-methylpyrrolidone, gamma-butyrolactone, toluene, xylene, mesitylene, naphthaline, anthracene, imidazole, oxazole, benzimidazole, benzoxazole, quinoline, quinoxaline, fulvalene, furan, pyrrole, thiophene and diphenyl sulfide.

70. The method of claim 66, wherein the aftertreatment reagent is present in a solution.

71. The method of claim 66, wherein the aftertreatment reagent is present as vapor.

72. The method of claim 66, wherein the aftertreatment time is between 15 seconds and 15 minutes.

73. The method of claim 66, wherein the aftertreatment takes place at a temperature of −30° C. to 150° C.

74. The method of claim 66, wherein in the process of contacting the first electrode with the organic material, the aftertreatment reagent is admixed with the solution containing the organic material or with the vapor containing the organic material.

75. The semiconductor arrangement of claim 45, wherein the compound is treated with an aftertreatment reagent and a reaction product of the aftertreatment reagent with the organic material or the electrode material.

76. A semiconductor arrangement with a bit line and a word line having a nonvolatile memory cell with a first electrode comprising at least two layers and an organic material, the organic material forming a compound with that layer of the first electrode which is in direct contact, wherein the nonvolatile memory cells are situated directly between bit and word lines that cross one another.

77. The semiconductor arrangement of claim 76, wherein the nonvolatile memory cells are present in a plurality of layers.

78. The semiconductor arrangement of claim 76, produced by the following steps in any desired order:
forming at least one first interconnect on a substrate, which serves as first electrode;
depositing an insulating layer;
patterning the insulating layer, so that in the insulating layer trenches are patterned for at least one interconnect transversely with respect to the first interconnects applied;
depositing an organic material; and
depositing at least one second electrode, which is arranged transversely with respect to the first interconnect applied and serves as a second electrode for the memory cell.

79. The semiconductor arrangement of claim 78, wherein the deposition of the insulating layer is effected after the deposition of the organic material.

80. The semiconductor arrangement of claim 77, produced by the following steps in this order:
forming at least one first interconnect on a substrate;
depositing an insulating layer;
patterning the contact holes above the first electrode;
depositing an organic material into the contact holes over the first electrode;
depositing a second insulating layer;
patterning the second insulating layer, so that in the insulating layer trenches are patterned for at least one second interconnect, which runs transversely with respect to the first interconnects applied and covers the contact holes in the cell array; and
depositing at least one second interconnect, which serves as a second electrode for the memory cell.

81. The semiconductor arrangement of claim 76, produced by a Cu damascene technique.

82. A method for producing a semiconductor arrangement comprising:
forming at least one first interconnect on a substrate, which serves as a first electrode for a memory cell;
depositing an insulating layer;
patterning the insulating layer, so that in insulating layer trenches are patterned for at least one interconnect transversely with respect to the first interconnects applied;
depositing an organic material;
depositing at least one second electrode, which is arranged transversely with respect to the first interconnect applied and serves as a second electrode for the memory cell.

83. The method of claim 82, further comprising effecting the deposition of the insulating layer after the deposition of the organic material.

84. A method for producing a semiconductor arrangement comprising:
applying at least one first interconnect on a substrate;
depositing an insulating layer;
patterning the contact holes above the first electrode;
depositing an organic material into the contact holes over the first electrode;
depositing a second insulating layer;
patterning the second insulating layer, so that in the insulating layer trenches are patterned for at least one second interconnect, which runs transversely with respect to the first interconnects applied and covers the contact holes in the cell array; and
depositing at least one second interconnect, which serves as a second electrode for the memory cell.

85. The method of claim 84, further comprising depositing a protective layer on the organic material after the deposition of the organic material prior to further processing.

86. New) The semiconductor arrangement of claim 45 configured as a memory device containing a plurality of the nonvolatile memory cells.

87. The semiconductor arrangement of claim 86, wherein a plurality of memory cells are arranged in one plane.

88. The semiconductor of claim 87, wherein a plurality of memory cells are arranged in the XY plane and in the XZ or YZ plane.
